(19) United States
(12) Patent Application Publication
(10) Pub. No.: US 2003/0085453 A1
(43) Pub. Date: May 8, 2003

(54) Flip chip semiconductor devices and heat sink assemblies, and the coupling thereof to form an electronic apparatus including a compliant support for supporting a heat sink

(75) Inventors: Lewis M. Eyman, Austin, TX (US); Thomas P. Dolbear, Austin, TX (US); Jabir M. Yusufali, Austin, TX (US)

Correspondence Address: B. NOEL KIVLIN, CONLEY, ROSE & TAYON, P.C., P.O. BOX 398, AUSTIN, TX, 78767-1400, US

(73) Assignee: Advance Micro Devices, Inc.

(21) Appl. No.: 10/210,486

(22) Filed: Aug. 1, 2002

Related U.S. Application Data
(63) Continuation of application No. 09/545,039, filed on Apr. 7, 2000, now abandoned.

(51) Int. Cl. H01L 23/02

(52) U.S. Cl. 257/678

(57) ABSTRACT

Several different embodiments of a semiconductor device and a heat sink assembly and are described, as well as methods for forming the embodiments. Methods for coupling corresponding embodiments of the heat sink assembly and the semiconductor device to form an electronic apparatus are also described, wherein the electronic apparatus includes a compliant support for supporting a heat sink. The semiconductor device includes an integrated circuit (IC) mounted upon an upper surface of a substrate. In a first embodiment of the semiconductor device, the compliant support is positioned about an outer region of the upper surface of the substrate surrounding the IC. In a second embodiment of the heat sink assembly, the compliant support is attached to an outer region of an underside surface of the heat sink. The compliant support responds to a compressive first force by producing a spring-like second force which opposes the first force. The first force may be produced by one or more clips used to urge the heat sink toward the substrate. The second force is preferably sufficient to maintain the underside surface of the heat sink substantially parallel to the upper surface of the substrate. In this case, the second force prevents damage to the IC and/or electrical connections between the IC and the substrate due to uneven pressure exerted upon a backside surface of the IC by the heat sink. Such damage may occur during the coupling operation, or during handling and/or transportation of the electronic apparatus.

### BACKGROUND OF THE INVENTION

1. Field of the Invention

This invention relates to electronic devices, and more particularly to electronic devices employing integrated circuits coupled to heat sinks.

2. Description of the Related Art

During operation, semiconductor devices such as integrated circuits dissipate electrical energy, thereby transforming electrical energy into heat energy. At the same time, several key operating parameters of a semiconductor device typically vary with temperature. The heat energy produced by the semiconductor device during operation must thus be removed to an ambient environment at a rate which ensures the temperature of the device remains within a specified operating temperature range.

Semiconductor device packages for housing integrated circuits which produce appreciable amounts of heat energy typically have accessible surfaces for mounting heat sinks which help remove heat energy from the packages. A thermal interface layer is typically formed between the heat sink and the accessible surface. One or more metal or plastic clips are typically used to hold the heat sink in place and to create a force between the heat sink and the device package. The thermal interface layer and the force created by the clips both tend to improve the thermal coupling between the heat sink and the device package, thus improving the transfer of heat energy from the device package to the heat sink.

As integrated circuit fabrication technology improves, manufacturers are able to integrate more and more functionality into a single IC. As the number of integrated functions increases, so do the number of signal lines which need to be connected to external devices. Accordingly, IC manufacturers are shifting from peripheral-terminal packages, with terminals arranged around a periphery of the package, to array semiconductor device packages having terminals arranged about an underside surface of the package. The physical dimensions of array device packages having hundreds of terminals are much smaller than their peripheral-terminal counterparts. Increasingly popular “flip chip” array packages include integrated circuits mounted in inverted orientations upon upper surfaces of larger substrates. Multiple terminals are arranged in a regular pattern about underside surfaces of the flip chip array packages.

Heat sinks for flip chip array devices are thermally coupled to upward facing backside surfaces of the integrated circuits. Heat sinks for high performance flip chip array devices which produce appreciable amounts of heat energy, such as microprocessors, tend to be relatively large and heavy. Lateral dimensions of such heat sinks tend to be closer to those of the substrate than those of the smaller integrated circuit.

During the coupling of a heat sink to a high performance flip chip array device package, the heat sink is pressed against the backside surface of the integrated circuit, and one or more clips may be engaged to keep the heat sink in place and to urge the heat sink toward the substrate. If the underside surface of the heat sink is not maintained in a position substantially parallel to the upward facing backside surface of the integrated circuit during the heat sink coupling operation, the resulting uneven pressure applied to the backside surface of the integrated circuit may damage the integrated circuit and/or the electrical connections between the integrated circuit and the substrate. Further, such damage may occur during handling and/or transportation if the clips allow the heat sink to rock from side to side across the backside surface of the integrated circuit.

It would thus be desirable to have a structure for supporting a heat sink coupled to a flip chip array package. The desired support structure would ensure that the underside surface of a heat sink is maintained substantially parallel to the upward facing backside surface of the integrated circuit during heat sink coupling as well as handling and/or transportation of the resultant electronic apparatus.

### SUMMARY OF THE INVENTION

Several different embodiments of a semiconductor device and a heat sink assembly and are described, as well as methods for forming the embodiments. Methods for coupling corresponding embodiments of the heat sink assembly and the semiconductor device to form an electronic apparatus are also described, wherein the electronic apparatus includes a compliant support for supporting a heat sink.

Described embodiments of the semiconductor device include a flip chip array device. The flip chip array device includes an integrated circuit (IC) mounted upon an upper surface of a substrate. The upper surface of the substrate has a center region and an outer region surrounding the center region. The substrate includes multiple electrically conductive bonding pads arranged within the center region and according to a pattern. The IC has opposed frontside and backside surfaces, and multiple input/output (I/O) pads arranged upon the frontside surface, where the arrangement of the I/O pads defines the pattern. Each I/O pad of the IC is coupled to a corresponding one of the bonding pads of the substrate. For example, each I/O pad may be coupled to a corresponding one of the bonding pads of the substrate by a solder bump.

The substrate may have multiple signal terminals (e.g., pins) arranged about an underside surface opposite the upper surface. The signal terminals may extend outwardly from the underside surface. The substrate may also include multiple electrical conductors connecting the bonding pads to corresponding signal terminals.

The upper and undersides surfaces of the substrate may be substantially planar. Similarly, the frontside and backside surfaces of the IC may be substantially planar. The IC may be is coupled to the center region of the upper surface of the substrate such that the backside surface of the IC is substantially parallel to the upper surface of the substrate.

A first embodiment of the semiconductor device includes the compliant support attached to the upper surface of the substrate within the outer region and arranged about the IC. The compliant support responds to a compressive first force by producing a spring-like second force which opposes the first force. For example, the compliant support may change shape under the compressive first force in a substantially elastic manner, thereby producing the second force. The material from which the compliant support is formed may include silicone rubber. The compliant support may also be formed from an elastomeric material. In the described embodiments, the compressive first force is used to urge the heat sink toward the substrate.

A corresponding first embodiment of the heat sink assembly includes the heat sink. The heat sink has an underside surface including a center region and an outer region surrounding the center region. A thermal interface layer is attached to the center region of the underside surface of the heat sink. During a coupling operation, the underside surface of the heat sink is positioned adjacent to the upper surface of the substrate of the semiconductor device. The thermal interface layer is positioned to contact the upward facing backside surface of the IC during the coupling operation, and is used to thermally couple the IC to the heat sink.

In a second embodiment of the semiconductor device, the thermal interface layer is attached to the upward facing backside surface of the IC. In a corresponding second embodiment of the heat sink assembly, the compliant support is attached to the underside surface of the heat sink within the outer region of the underside surface.

In the described embodiments, the compliant support has opposed upper and underside surfaces, and a substantially uniform dimension (e.g., thickness) exists between the upper and underside surfaces. The upward facing backside surface of the integrated circuit is at a first elevation above the upper surface of the substrate. In the first embodiment of the semiconductor device, the upper surface of the compliant support is at a second elevation above the upper surface of the substrate, where the second elevation is greater than the first elevation.

During the coupling operation, the heat sink assembly is lowered over the semiconductor device. When the coupling involves the first embodiments of the semiconductor device and the heat sink assembly, the upper surface of the compliant support is at a higher elevation above the upper surface of the substrate than the backside surface of the IC. As a result, the underside surface of the heat sink first contacts the upper surface of the compliant support. Thus during an initial portion of the coupling operation, the compliant support not only serves to orient the underside surface of heat sink substantially parallel to the upper surface of substrate, the compliant support also prevents the underside surface of the heat sink from contacting brittle edges of the backside surface of the IC.

The compliant support may substantially surround the IC. In this case, the compliant support may be a continuous ring encircling the IC. Alternately, the compliant support may include multiple separate sections arranged about the IC such that the separate sections substantially surround the IC. In other embodiments, the compliant support may include two separate sections positioned on opposite sides of the IC.

For example, the upper surface of the substrate may be substantially rectangular, thus having two pairs of opposite edges and four corners. The compliant support may include four separate rectangular bars each positioned near a different edge of the upper surface of the substrate. Alternately, the compliant support may include two separate rectangular bars positioned on opposite sides of the IC near opposite edges of the upper surface of the substrate. In yet another embodiment, the compliant support may include four separate sections (e.g., rectangular, circular, etc.) each positioned in a different corner of the upper surface of the substrate.

The electronic apparatus is produced by the coupling operation. The electronic apparatus thus includes the substrate, the IC mounted upon the center region of the upper surface of the substrate, the heat sink, and the compliant support. The compliant support is positioned between, and in contact with, the outer region of the upper surface of the substrate and the outer region of the underside surface of the heat sink.

A first force (e.g., produced by one or more clips) urges the heat sink toward the substrate. The first force compresses the compliant support between the underside surface of the heat sink and the upper surface of the substrate. The compressed compliant support produces a spring-like second force which opposes the first force. The compliant support may, for example, change shape under the first force in a substantially elastic manner, thereby producing the second force. The second force is preferably sufficient to substantially maintain an orientation of the underside surface of the heat sink with respect to the upper surface of the substrate. In this case, the second force prevents damage to the IC and/or electrical connections between the IC and the substrate due to uneven pressure exerted upon the backside surface of the IC by the heat sink. Such damage may occur during the coupling operation, or during handling and/or transportation of the electronic apparatus.

For example, the upper surface of the substrate, the underside surface of the heat sink, and the backside surface of the IC may be substantially planar. Further, the backside surface of the IC may be substantially parallel to the upper surface of the substrate. In this case, the second force produced by the compliant support about the IC is preferably sufficient to maintain the underside surface of the heat sink substantially parallel to the upper surface of the substrate such that the second force prevents damage to the IC and/or the electrical connections between the IC and the substrate.

In one embodiment of the electronic apparatus, the substrate has a substantially planar upper surface, and the IC has substantially planar frontside and backside surfaces. The frontside surface of the IC is coupled to the center region of the upper surface of the substrate such that the backside surface of the IC is substantially parallel to the upper surface of the substrate. For example, I/O pads of the IC may be coupled to corresponding bonding pads of the substrate as described above. The heat sink has a substantially planar underside surface. The thermal interface layer is positioned between the underside surface of the heat sink and the backside surface of the IC such that the underside surface of the heat sink is thermally coupled to the backside surface of the IC.

The first force urges the heat sink toward the substrate as described above, and compresses the compliant support between the underside surface of the heat sink and the upper surface of the substrate. The compressed compliant support produces the spring-like second force which opposes the first force as described above. The first force also compresses the thermal interface layer between the underside surface of the heat sink and the backside surface of the IC. The compressed thermal interface layer produces a spring-like third force which opposes the first force. The second and third forces add to oppose the first force. The second force produced by the compliant support about the IC may be sufficient to maintain the underside surface of the heat sink substantially parallel to the upper surface of the substrate.

A magnitude of the second force produced by the compliant support may decrease with time due to compression set. Further, the magnitude of the second force may go to zero over time. Where the first force remains substantially constant and the magnitude of the second force decreases with time, the third force produced by the thermal interface layer necessarily increases with time. Where the first force remains substantially constant and the magnitude of the second force decreases to zero over a given amount of time, the third force produced by the thermal interface layer must increase over the given amount of time to become equal to the first force.

Two methods for forming a semiconductor device include providing the substrate and the IC described above, and coupling the I/O pads of the IC to corresponding bonding pads of the substrate. A first method further includes arranging the above described compliant support about the IC and attaching the compliant support to the upper surface of the substrate within the outer region. As described above, the compliant support is adapted to respond to a compressive first force by producing a spring-like second force which opposes the first force. A second method further includes attaching a thermal interface layer to the backside surface of the integrated circuit, wherein the thermal interface layer is dimensioned to substantially cover the backside surface.

A method for forming an electronic apparatus including the above described compliant support includes positioning the compliant support upon a surface of a substrate and about an IC mounted upon the surface of the substrate. A surface of a heat sink is positioned adjacent to the surface of the substrate. A first force is applied between the heat sink and the substrate such that the compliant support is compressed between the surface of the heat sink and the surface of the substrate. Under the compressive first force, the compliant support produces a second force which opposes the first force. The compliant support may change shape under the first force in a substantially elastic manner as described above, thereby producing the second force. The second force is preferably sufficient to maintain an orientation of the surface of the heat sink with respect to the surface of the substrate as described above. The first force may have sufficient magnitude to overcome the second force and to achieve thermal coupling between the heat sink and the IC. Further, the first force may have sufficient magnitude to achieve a desired value of thermal resistance between the heat sink and the IC.

### BRIEF DESCRIPTION OF THE DRAWINGS

Other objects and advantages of the invention will become apparent upon reading the following detailed description and upon reference to the accompanying drawings in which:

FIG. 1 is a cross sectional view illustrating a coupling operation wherein a heat sink assembly is coupled to a semiconductor device to form an electronic apparatus, and wherein the semiconductor device includes a compliant support positioned upon an upper surface of a substrate and arranged about an integrated circuit (IC) coupled to a center region of the upper surface of the substrate, and wherein the heat sink assembly includes a heat sink and a thermal interface layer attached to a center region of an underside surface of the heat sink;

FIG. 2 is a cross sectional view illustrating the coupling operation wherein the semiconductor device includes the IC coupled to the center region of the upper surface of the substrate and the thermal interface layer attached to an upward facing backside surface of the IC, and wherein the heat sink assembly includes the compliant support attached to an outer region of the underside surface of the heat sink;

FIG. 3 is a cross sectional view of the electronic apparatus of FIGS. 1 and 2 wherein a first force F is applied between the heat sink and the substrate, and wherein under the compressive first force the compliant support produces a spring-like second force about the IC which opposes the first force;

FIG. 4 is a top plan view of the semiconductor device of FIG. 1 including a first embodiment of the compliant support wherein the compliant support is a continuous ring positioned upon the upper surface of the substrate such that the compliant support encircles the IC;

FIG. 5 is a top plan view of the semiconductor device of FIG. 1 including a second embodiment of the compliant support wherein the compliant support includes four separate rectangular bars each positioned near a different edge of the rectangular upper surface of the substrate such that the four rectangular bars completely surround the IC;

FIG. 6 is a top plan view of the semiconductor device of FIG. 1 including a third embodiment of the compliant support wherein two rectangular bars are positioned near opposite edges of the upper surface of the substrate on opposite sides of the IC;

FIG. 7 is a top plan view of the semiconductor device of FIG. 1 including a fourth embodiment of the compliant support wherein the compliant support includes four rectangular sections positioned in different corners of the rectangular upper surface of the substrate; and

FIG. 8 is a top plan view of the semiconductor device of FIG. 1 including a fifth embodiment of the compliant support wherein the compliant support includes four round sections positioned in different corners of the rectangular upper surface of the substrate.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

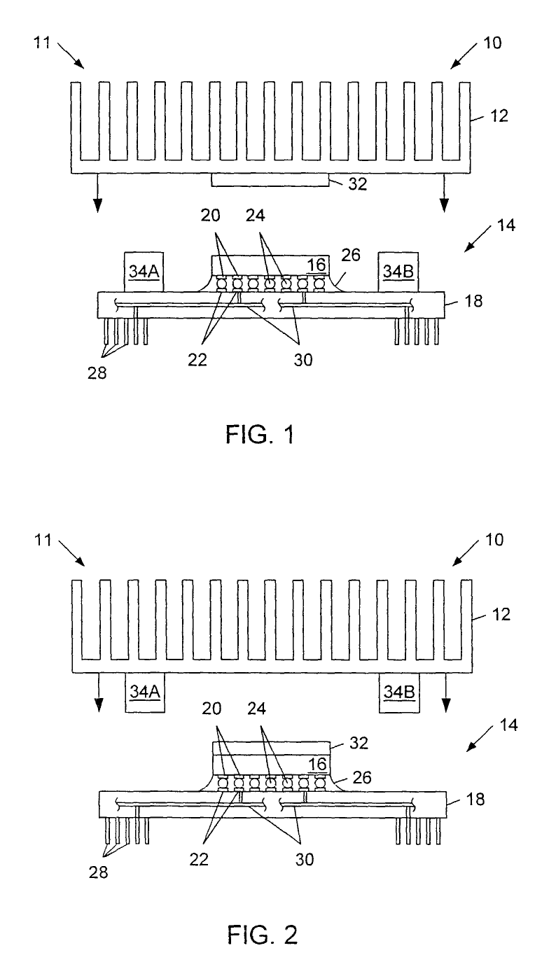

FIGS. 1 and 2 are cross sectional views illustrating the coupling of corresponding embodiments of a heat sink assembly 11 and a semiconductor device 14 to form an electronic apparatus 10. Other embodiments of heat sink assembly 11 and semiconductor device 14 are contemplated. In the embodiments of FIGS. 1 and 2, heat sink assembly 11 includes a heat sink 12 used to remove heat energy from semiconductor device 14 to a surrounding ambient.

In the embodiments of FIGS. 1 and 2, semiconductor device 14 includes an integrated circuit (IC) 16 mounted upon an upper surface of a substrate 18. The upper surface of substrate 18 is substantially planar such that IC 16 extends above the upper surface of substrate 18. IC 16 may be, for example, a microprocessor, and electronic apparatus 10 including IC 16 may be part of a computer system.

IC 16 has opposed frontside and backside surfaces. Multiple input/output (I/O) pads 20 are arranged upon the frontside surface of IC 16, defining a pattern. The upper surface of substrate 18 has an outer region surrounding a center region. Multiple electrically conductive bonding pads 22 are arranged in the center region of the upper surface according to the pattern. Using the well known controlled collapse chip connection (C4) or “flip chip” method, I/O pads 20 of IC 16 are coupled to corresponding bonding pads 22 of substrate 18 by solder bumps 24. That is, each I/O pad 20 is coupled to corresponding one of the bonding pads 22 by a solder bump 24. A layer 26 of an underfill material is used to encapsulate the C4 solder bump connections in the region between IC 16 and substrate 18.

Substrate 18 is preferably formed substantially of a ceramic material (e.g., aluminum oxide or aluminum nitride). Alternately, substrate 18 may be formed substantially of a fiberglass-epoxy printed circuit board material or a plastic material.

Substrate 18 has multiple conductive pins 28 arrange upon and extending outwardly from the underside surface. Pins 28 are provided for connecting to a printed circuit board (PCB) or for inserting into a socket. In other embodiments of semiconductor device 14, substrate 18 may employ other types of terminals (e.g., solder balls) in place of pins 28.

Substrate 18 includes multiple electrical conductors 30 connecting bonding pads 22 to corresponding pins 28. Electrical signals are routed to and from IC 16 via electrical conductors 30. Electrical conductors 30 may include multiple horizontal layers of electrical conductors in a stacked arrangement, where adjacent layers are electrically isolated from one another by a dielectric material used to form substrate 18. Vertical conductive vias connect bonding pads 22 to corresponding electrical conductors 30, and electrical conductors 30 to corresponding pins 28.

FIG. 1 is a cross sectional view illustrating the coupling of a first embodiment of heat sink assembly 11 to a first embodiment of semiconductor device 14 to form electronic apparatus 10. In the first embodiment of FIG. 1, heat sink apparatus 11 includes a thermal interface layer 32 attached to a center region of an underside surface of heat sink 12. The center region of the underside surface of heat sink 12 is directly above the center region of the upper surface of substrate 18, and directly above an upward facing backside surface of IC 16.

In the first embodiment of FIG. 1, semiconductor device 14 includes a compliant support 34 positioned upon an upper surface of substrate 18 and arranged about IC 16. An underside surface of compliant support 34 may, for example, be adhesively attached to the upper surface of substrate 18. Cross-sectional portions 34A and 34B of compliant support 34 appear in FIGS. 1 and 2.

FIG. 2 is a cross sectional view illustrating the coupling of a second embodiment of heat sink assembly 11 to a second embodiment of semiconductor device 14 to form electronic apparatus 10. In the second embodiment of FIG. 2, an upper surface of compliant support 34 is attached to the underside surface of heat sink 12. Compliant support 34 is arranged about an outer region of the underside surface of heat sink 12 surrounding the center region. In the second embodiment of FIG. 2, semiconductor device 14 includes thermal interface layer 32 attached to the upward facing backside surface of IC 16.

As noted above, other embodiments of heat sink assembly 11 and semiconductor device 14 are contemplated. For example, another embodiment semiconductor device 14 may include compliant support 34 attached to the upper surface of the substrate within the outer region and arranged about the IC, and thermal interface layer 32 attached to the upward facing backside surface of IC 16.

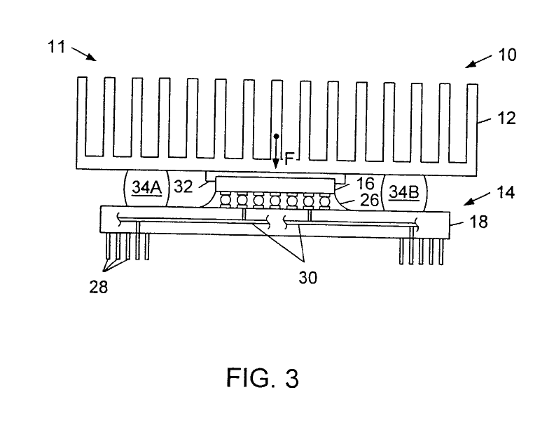

FIG. 3 is a cross sectional view of the electronic apparatus 10 of FIGS. 1 and 2 during the coupling of heat sink assembly 11 to semiconductor device 14. During a initial portion of the coupling of heat sink assembly 11 to semiconductor device 14, heat sink assembly 11 is lowered over semiconductor device 14 until the upper surface of compliant support 34 contacts the underside surface of heat sink 12 and the underside surface of compliant support 34 contacts the upper surface of substrate 18. In FIG. 1, the underside surface of compliant support is in contact with (e.g., attached to) the upper surface of substrate 18 prior to the coupling. Heat sink assembly 11 is lowered over semiconductor device 14 until the underside surface of heat sink 12 contacts the upper surface of complaint support 34. In FIG. 2, the upper surface of compliant support is attached to and in contact with the underside surface of heat sink 12 prior to the coupling. Heat sink assembly 11 is lowered over semiconductor device 14 until the underside surface of compliant support 34 contacts the upper surface of substrate 18.

Compliant support 34 has a substantially uniform dimension (e.g., thickness) between the opposed upper and underside surfaces such that when the upper surface of compliant support 34 contacts the underside surface of heat sink 12 and the underside surface of compliant support 34 contacts the upper surface of substrate 18, the underside surface of heat sink 12 is substantially parallel to the upper surface of substrate 18. Thus during the initial portion of the coupling, compliant support 34 serves to orient the underside surface of heat sink 12 substantially parallel to the upper surface of substrate 18.

The dimension of compliant support 34 between the opposed upper and underside surfaces is also greater than an elevation of the upward facing backside surface of IC 16 above the upper surface of substrate 18. Thus during the initial portion of the coupling, compliant support 34 also serves to prevent the underside surface of heat sink 12 from contacting brittle edges of the backside surface of IC 16.

A first force is then applied between heat sink 12 and substrate 18 which urges heat sink 12 toward substrate 18. Compliant support 34 is made from a material which changes shape in a substantially elastic manner when subjected to mechanical stress. As compliant support 34 is compressed under the first force, a vertical height of compliant support 34 decreases and a horizontal width of compliant support 34 increases.

In response to the compressive first force, complaint support 34 produces a spring-like second force about IC 16 which opposes the first force. The second force tends to maintain a desired parallel orientation of the underside surface of heat sink 12 with respect to the upper surface of substrate 18.

The magnitude of the first force exerted between heat sink 12 and substrate 18 is increased to a first magnitude sufficient to compress compliant support 34 until an underside surface of thermal interface layer 32 contacts the upward facing backside surface of IC 16. The first magnitude is dependent upon the modulus of the elastic material from which compliant support 34 is formed, the cross sectional shape of complaint support 34, the contact area between compliant support 34 and the upper surface of substrate 18, the contact area between compliant support 34 and the underside surface of heat sink 12, and the change in height of complaint support 34 under the first magnitude.

If necessary, the magnitude of the first force is then increased to a second magnitude in order to compress thermal interface layer 32 to obtain a desired value of thermal resistance between IC 16 and heat sink 12. FIG. 2 is a cross sectional view of electronic apparatus 10 with first force F applied between heat sink 12 and substrate 18, wherein the magnitude of first force F is sufficient to achieve the desired value of thermal resistance between IC 16 and heat sink 12. The second magnitude of first force F may or may not be greater than the first magnitude dependent upon the material used to form thermal interface layer 32. One or more metal or plastic clips (not shown) may be engaged to maintain the second magnitude of first force F between heat sink 12 and substrate 18.

In a preferred embodiment, thermal interface layer 32 is formed from a thermally conductive material which is substantially solid at room temperature and changes phase (i.e., flows) at operating temperatures of electronic apparatus 10. For example, thermal interface layer 32 may be a phase-change thermal interface pad. A suitable phase-change thermal interface pad is the THERMFLOW•T725 phase-change thermal interface pad (Chomerics Co., Woburn, Mass.) having a suggested heat sink/component clamping pressure range of 5-100 PSI. The second magnitude of first force F is greater than the first magnitude by at least an amount obtained by multiplying a selected heat sink/component clamping pressure by the area of the upper surface if IC 16.

Thermal interface layer 32 may be formed from a material which is tacky at room temperature and readily adheres to a desired surface. Alternately, thermal interface layer 32 may be formed from a material which becomes tacky at a temperature greater than room temperature. In this case, attaching thermal interface layer 32 to the desired surface may involve heating thermal interface layer 32 until the material becomes tacky and readily adheres to the desired surface.

In other embodiments, thermal interface layer 32 may be a layer of thermal grease, thermal wax, or a piece of thermal interface tape. Except in cases where no pressure is required between heat sink 12 and IC 16 to obtain the desired value of thermal resistance, the second magnitude of first force F is necessarily greater than the first magnitude.

As described above, when compliant support 34 is subjected to compressive first force F, compliant support 34 produces a spring-like second force about IC 16 which opposes first force F. Where a positive pressure is required between heat sink 12 and IC 16 to obtain the desired value of thermal resistance, thermal interface layer 32 produces a third force between IC 16 and heat sink 12 which opposes first force F. In this case, the third force produced by thermal interface layer 32 sums with the second force produced by compliant support 34 to oppose first force F. The second force produced by compliant support 34 is preferably substantially equal to any third force produced by thermal interface layer 32, and is preferably sufficient to ensure that the underside surface of heat sink 12 stays substantially parallel to the upward facing backside surface of IC 16 during the heat sink coupling operation described above as well as during handling and/or transportation of resultant electronic apparatus 10. In other words, the second force produced by compliant support 34 is preferably sufficient to prevent heat sink 12 from rocking from side to side across the backside surface of IC 16. Such rocking may cause damage to IC 16, or to the electrical connections between IC 16 and substrate 18, due to uneven pressure exerted upon the backside surface of IC 16 by heat sink 12.

Compliant support 34 may be formed from a silicone rubber compound. A suitable material for compliant support 34 is the Fralock HT-820 silicone rubber compound (Fralock Div., Lockwood Industries, Canoga Park. Calif.). Table 1 below lists the physical properties of the Fralock HT-820 silicone rubber compound.

TABLE 1
Physical Properties of Fralock HT-820 Silicone Rubber Compound.

| Physical Property | Test Method | Value |
|---|---|---|
| Compression Force Deflection, | | |
| psi (kpa) @ 25% deflection | ASTM D-1056 | 14 (97) |
| Compression Set @ 70 · C. (158 · F.) | ASTM D-1056 | <1% |
| Compression Set @ 100 · C. (212 · F.) | ASTM D-1056 | <5% |
| Density, lb/ft³(kg/m³) | ASTM D-3574 | 24 (384) |
| Tensile Strength, psi (kpa) | ASTM D-412 | 60 (414) |
| Elongation, % | ASTM D-412 | 65 |

Compliant support 34 may also be formed from any one of various elastomeric materials with an acceptable resistance to relaxation over time and a range of temperatures compliant support 34 is expected to experience.

It is noted that due to compression set, the magnitude of the second force produced by compliant support 34 and opposing first force F expectedly decreases with time. Further, the magnitude of the second force produced compliant support 34 may go to zero over time. Where first force F remains substantially constant and the magnitude of the second force decreases with time, the third force produced by thermal interface layer 32 necessarily increases with time. Where first force F remains substantially constant and the magnitude of the second force decreases to zero over a given amount of time, the third force produced by thermal interface layer 32 must increase over the given amount of time to become equal to first force F.

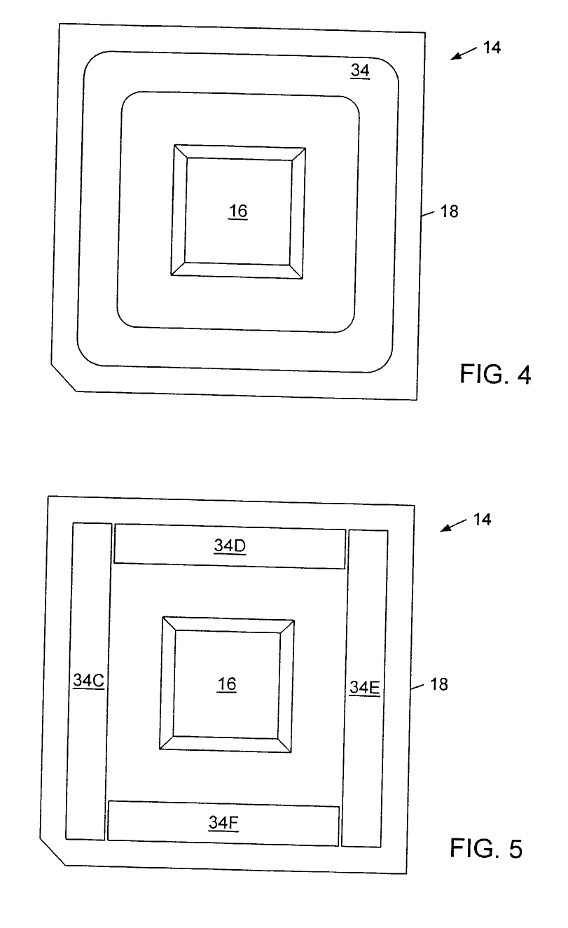

FIGS. 4-8 illustrate different embodiments of compliant support 34. FIG. 4 is a top plan view of semiconductor device 14 of FIG. 1 including a first embodiment of compliant support 34 wherein compliant support 34 is a continuous ring positioned upon the upper surface of substrate 18 such that compliant support 34 encircles IC 16.

FIG. 5 is a top plan view of semiconductor device 14 of FIG. 1 including a second embodiment of compliant support 34 wherein compliant support 34 includes four separate rectangular bars 34C-34F each positioned near a different edge of the rectangular upper surface of substrate 18 such that the four rectangular bars 34C-34F completely surround IC 16.

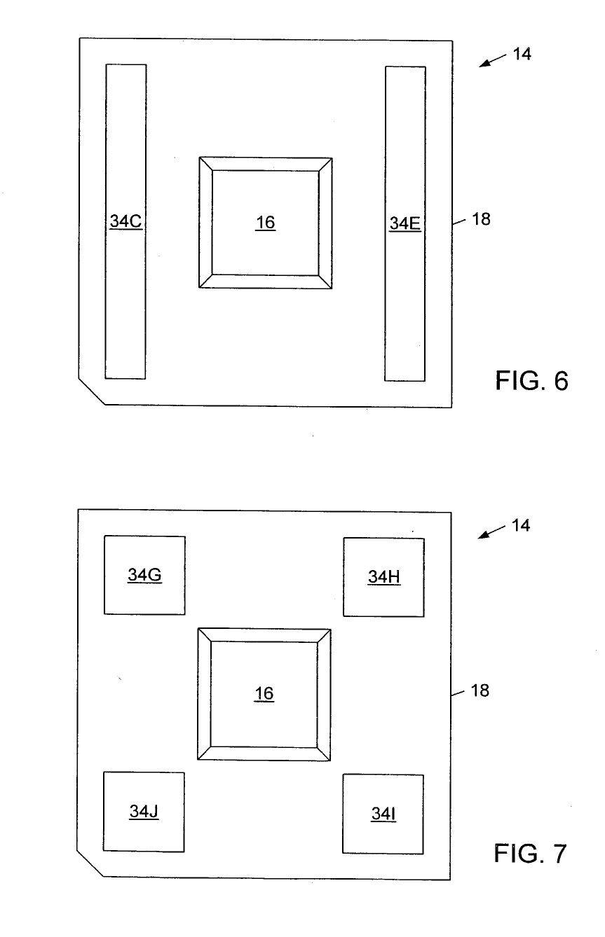

FIG. 6 is a top plan view of semiconductor device 14 of FIG. 1 including a third embodiment of compliant support 34 wherein the embodiment of FIG. 5 is modified such that rectangular bars 34D and 34F are eliminated, leaving rectangular bars 34C and 34E positioned near opposite edges of the upper surface of substrate 18 on opposite sides of IC 16.

FIG. 7 is a top plan view of semiconductor device 14 of FIG. 1 wherein compliant support 34 includes four rectangular sections 34G-34J positioned in different corners of the rectangular upper surface of substrate 18.

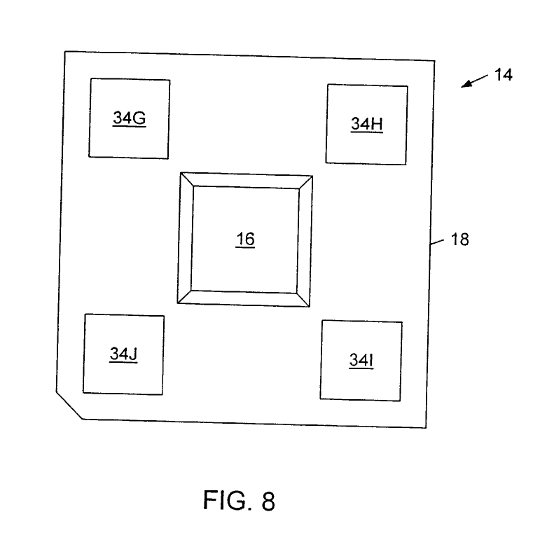

FIG. 8 is a top plan view of semiconductor device 14 of FIG. 1 wherein sections 34G-34J of compliant support 34 of FIG. 7, positioned in different corners of the rectangular upper surface of substrate 18, are round instead of rectangular.

It is noted that the embodiments of compliant support 34 illustrated in FIGS. 4-8 may also be attached to the outer region of the underside surface of heat sink 12 as indicated in FIG. 2.

Although compliant support 34 is shown having rectangular cross sections in the embodiments of FIGS. 1-8, it is noted that compliant support 34 have any number of other cross sectional shapes, including trapezoidal, round, and triangular.

Numerous variations and modifications will become apparent to those skilled in the art once the above disclosure is fully appreciated. It is intended that the following claims be interpreted to embrace all such variations and modifications.

What is claimed is:

1. A semiconductor device, comprising:
a substrate having opposed upper and underside surfaces, wherein the upper surface has a center region and an outer region surrounding the center region, and wherein the substrate comprises a plurality of electrically conductive bonding pads arranged within the center region and according to a pattern;
an integrated circuit (IC) having opposed frontside and backside surfaces, wherein the frontside surface has a plurality of input/output (I/O) pads arranged thereupon, and wherein the arrangement of the I/O pads defines the pattern, and wherein each I/O pad is coupled to a corresponding one of the bonding pads of the substrate; and
a compliant support attached to the upper surface of the substrate within the outer region and arranged about the IC, wherein the compliant support is adapted to respond to a compressive first force by producing a spring-like second force which opposes the first force.

2. The semiconductor device as recited in claim 1, wherein the substrate further comprises a plurality of signal terminals arranged about the underside surface and extending outwardly from the underside surface.

3. The semiconductor device as recited in claim 2, wherein the substrate further comprises a plurality of electrical conductors connecting the bonding pads to corresponding signal terminals.

4. The semiconductor device as recited in claim 1, wherein each I/O pad is coupled to the corresponding one of the bonding pads of the substrate by a solder bump.

5. The semiconductor device as recited in claim 1, wherein the compliant support is adapted to receive a surface of a heat sink, and wherein the compressive first force urges the heat sink toward the substrate, and wherein the compliant support is adapted to change shape under the compressive first force in a substantially elastic manner, thereby producing the second force.

6. The semiconductor device as recited in claim 1, wherein the compliant support has opposed upper and underside surfaces, and wherein a substantially uniform dimension exists between the upper and underside surfaces.

7. The semiconductor device as recited in claim 6, wherein the backside surface of the integrated circuit is at a first elevation above the upper surface of the substrate, and wherein the upper surface of the compliant support is at a second elevation above the upper surface of the substrate, and wherein the second elevation is greater than the first elevation.

8. The semiconductor device as recited in claim 1, wherein the compliant support comprises silicone rubber.

9. The semiconductor device as recited in claim 1, wherein the compliant support is formed from an elastomeric material.

10. The semiconductor device as recited in claim 1, wherein the compliant support substantially surrounds the IC.

11. The semiconductor device as recited in claim 10, wherein the compliant support is a continuous ring encircling the IC.

12. The semiconductor device as recited in claim 1, wherein the compliant support comprises a plurality of separate sections arranged about the IC.

13. The semiconductor device as recited in claim 12, wherein the compliant support comprises two separate sections attached to the upper surface of the substrate on opposite sides of the IC.

14. The semiconductor device as recited in claim 1, wherein the upper surface of the substrate is substantially rectangular and has two pairs of opposite edges and four corners.

15. The semiconductor device as recited in claim 14, wherein the compliant support comprises four separate rectangular bars each attached to the upper surface of the substrate near a different edge of the surface of the substrate.

16. The semiconductor device as recited in claim 14, wherein the compliant support comprises two separate rectangular bars attached to the upper surface of the substrate on opposite sides of the IC near opposite edges of the upper surface of the substrate.

17. The semiconductor device as recited in claim 14, wherein the compliant support comprises four separate sections each positioned in a different corner of the upper surface of the substrate.

18. A semiconductor device, comprising:
a substrate having opposed upper and underside surfaces, wherein the upper surface has a center region and an outer region surrounding the center region, and wherein the substrate comprises a plurality of electrically conductive bonding pads arranged within the center region and according to a pattern;
an integrated circuit having opposed frontside and backside surfaces, wherein the frontside surface has a plurality of input/output (I/O) pads arranged thereupon, and wherein the arrangement of the I/O pads defines the pattern, and wherein each I/O pad is coupled to a corresponding one of the bonding pads of the substrate; and
a thermal interface layer attached to the backside surface of the integrated circuit.

19. The semiconductor device as recited in claim 18, wherein the substrate further comprises a plurality of signal terminals arranged about the underside surface and extending outwardly from the underside surface.

20. The semiconductor device as recited in claim 19, wherein the substrate further comprises a plurality of electrical conductors connecting the bonding pads to corresponding signal terminals.

21. The semiconductor device as recited in claim 18, wherein each I/O pad is coupled to the corresponding one of the bonding pads of the substrate by a solder bump.

22. The semiconductor device as recited in claim 18, wherein the thermal interface layer is formed from a thermally conductive material which is substantially solid at room temperature and changes phase at operating temperatures of the IC.

23. The semiconductor device as recited in claim 22, wherein the thermal interface layer is a phase-change thermal interface pad.

24. An electronic apparatus, comprising:
a substrate including a surface having a center region and an outer region surrounding the center region;
an integrated circuit (IC) mounted to the center region of the surface of the substrate and having an accessible surface;
a heat sink having a surface thermally coupled to the accessible surface of the IC;
a compliant support positioned between the outer region of the surface of the substrate and the surface of the heat sink; and
wherein a first force urges the heat sink toward the substrate, and wherein the first force compresses the compliant support between the surface of the heat sink and the surface of the substrate, and wherein the compressed compliant support produces a spring-like second force which opposes the first force.

25. The electronic apparatus as recited in claim 24, wherein the compliant support changes shape under the first force in a substantially elastic manner, thereby producing the second force.

26. The electronic apparatus as recited in claim 24, wherein the second force is sufficient to substantially maintain an orientation of surface of the heat sink with respect to the surface of the substrate.

27. The electronic apparatus as recited in claim 24, wherein the surface of the substrate, the accessible surface of the IC, and the surface of the heat sink are substantially planar, and wherein the accessible surface of the IC is substantially parallel to the surface of the substrate, and wherein the second force produced by the compliant support about the IC is sufficient to maintain the surface of the heat sink substantially parallel to the surface of the substrate.

28. The electronic apparatus as recited in claim 24, wherein the compliant support comprises silicone rubber.

29. The electronic apparatus as recited in claim 24, wherein the compliant support is formed from an elastomeric material.

30. The electronic apparatus as recited in claim 24, wherein the compliant support substantially surrounds the IC.

31. The electronic apparatus as recited in claim 24, wherein the compliant support comprises a plurality of separate sections arranged about the IC.

32. The electronic apparatus as recited in claim 24, wherein the compliant support comprises two separate sections positioned on opposite sides of the IC.

33. The electronic apparatus as recited in claim 24, wherein the compliant support is a continuous ring encircling the IC.

34. The electronic apparatus as recited in claim 24, wherein the surface of the substrate is substantially rectangular and has two pairs of opposite edges and four corners.

35. The electronic apparatus as recited in claim 34, wherein the compliant support comprises four separate rectangular bars each positioned near a different edge of the surface of the substrate.

36. The electronic apparatus as recited in claim 34, wherein the compliant support comprises two separate rectangular bars positioned on opposite sides of the IC near opposite edges of the surface of the substrate.

37. The electronic apparatus as recited in claim 34, wherein the compliant support comprises four separate sections each positioned in a different corner of the surface of the substrate.

38. An electronic apparatus, comprising:
a substrate including a substantially planar upper surface having a center region and an outer region surrounding the center region;
an integrated circuit (IC) comprising a substantially planar frontside surface and an opposed substantially planar backside surface, wherein the frontside surface of the IC is coupled to the center region of the upper surface of the substrate such that the backside surface of the IC is substantially parallel to the upper surface of the substrate;
a heat sink having a substantially planar underside surface;
a thermal interface layer positioned between the underside surface of the heat sink and the backside surface of the IC such that the underside surface of the heat sink is thermally coupled to the backside surface of the IC;
a compliant support positioned between the outer region of the upper surface of the substrate and the underside surface of the heat sink;
wherein a first force urges the heat sink toward the substrate, and wherein the first force compresses the compliant support between the underside surface of the heat sink and the upper surface of the substrate, and wherein the compressed compliant support produces a spring-like second force which opposes the first force; and
wherein the first force compresses the thermal interface layer between the underside surface of the heat sink and the backside surface of the IC, and wherein the compressed thermal interface layer produces a spring-like third force which opposes the first force.

39. The electronic apparatus as recited in claim 38, wherein the compliant support changes shape under the first force in a substantially elastic manner, thereby producing the second force.

40. The electronic apparatus as recited in claim 38, wherein the second force produced by the compliant support about the IC is sufficient to maintain the underside surface of the heat sink substantially parallel to the upper surface of the substrate.

41. The electronic apparatus as recited in claim 38, wherein a magnitude of the second force produced by the compliant support about the IC decreases with time due to compression set such that the magnitude of the second force is greater than or equal to zero.

42. The electronic apparatus as recited in claim 38, wherein the compliant support comprises silicone rubber.

43. The electronic apparatus as recited in claim 38, wherein the compliant support is formed from an elastomeric material.

44. The electronic apparatus as recited in claim 38, wherein the compliant support substantially surrounds the IC.

45. The electronic apparatus as recited in claim 38, wherein the compliant support comprises a plurality of separate sections arranged about the IC.

46. The electronic apparatus as recited in claim 38, wherein the compliant support comprises two separate sections positioned on opposite sides of the IC.

47. The electronic apparatus as recited in claim 38, wherein the IC comprises a plurality of input/output (I/O) pads arranged upon the frontside surface defining a pattern, and wherein the substrate comprises a plurality of bonding pads arranged about the center region of the upper surface according to the pattern, and wherein each I/O pad of the IC is coupled to a corresponding bonding pad of the substrate.

48. A method for forming a semiconductor device, comprising:
providing:
a substrate having opposed upper and underside surfaces, wherein the upper surface has a center region and an outer region surrounding the center region, and wherein the substrate comprises a plurality of electrically conductive bonding pads arranged within the center region and according to a pattern;
an integrated circuit (IC) having opposed frontside and backside surfaces, wherein the frontside surface has a plurality of input/output (I/O) pads arranged thereupon, and wherein the arrangement of the I/O pads defines the pattern;
coupling the I/O pads of the IC to corresponding bonding pads of the substrate; and
arranging a compliant support about the IC and attaching the compliant support to the upper surface of the substrate within the outer region, wherein the compliant support is adapted to respond to a compressive first force by producing a spring-like second force which opposes the first force.

49. A method for forming a semiconductor device, comprising:
providing:
a substrate having opposed upper and underside surfaces, wherein the upper surface has a center region and an outer region surrounding the center region, and wherein the substrate comprises a plurality of electrically conductive bonding pads arranged within the center region and according to a pattern;
an integrated circuit (IC) having opposed frontside and backside surfaces, wherein the frontside surface has a plurality of input/output (I/O) pads arranged thereupon, and wherein the arrangement of the I/O pads defines the pattern;
coupling the I/O pads of the IC to corresponding bonding pads of the substrate; and
attaching a thermal interface layer to the backside surface of the integrated circuit, wherein the thermal interface layer is dimensioned to substantially cover the backside surface.

50. A method for forming an electronic apparatus, comprising:
positioning a compliant support upon a surface of a substrate and about an integrated circuit (IC) mounted upon the surface of the substrate;
positioning a surface of a heat sink adjacent to the surface of the substrate; and
applying a first force between the heat sink and the substrate such that the compliant support is compressed between the surface of the heat sink and the surface of the substrate and produces a second force which opposes the first force.

51. The method as recited in claim 50, wherein the compliant support changes shape under the first force in a substantially elastic manner, thereby producing the second force.

52. The method as recited in claim 50, wherein the second force is sufficient to substantially maintain an orientation of the surface of the heat sink with respect to the surface of the substrate.

53. The method as recited in claim 50, wherein the first force has sufficient magnitude to overcome the second force.

54. The method as recited in claim 50, wherein the first force has sufficient magnitude to thermally couple the heat sink to the IC.

55. The method as recited in claim 50, wherein the first force has sufficient magnitude to achieve a desired value of thermal resistance between the heat sink and the IC.

56. A method for forming an electronic apparatus, comprising:
attaching a compliant support to a surface of a heat sink;
positioning the surface of the heat sink adjacent to a surface of a substrate having an integrated circuit mounted thereupon; and
applying a first force between the heat sink and the substrate such that the compliant support is compressed between the surface of the heat sink and the surface of the substrate and produces a second force which opposes the first force.
